(19) United States
(12) Patent Application Publication
(10) Pub. No.: US 2020/0113083 A1
(43) Pub. Date: Apr. 9, 2020

(54) SYSTEM AND METHOD FOR COOLING ELECTRONIC DEVICES

(71) Applicant: Villanova University, Villanova, PA (US)

(72) Inventors: Steven G. Schon, Strafford, PA (US); Alfonso Ortega, Villanova, PA (US)

(73) Assignee: Villanova University, Villanova, PA (US)

(21) Appl. No.: 16/593,418

(22) Filed: Oct. 4, 2019

Related U.S. Application Data
(60) Provisional application No. 62/741,819, filed on Oct. 5, 2018.

(51) Int. Cl. H05K 7/20

(52) U.S. Cl. CPC H05K 7/20309; H05K 7/20509; H05K 7/20327; H05K 7/20318

(57) ABSTRACT

A system and a method are provided for cooling heat-generating devices. A plurality of heat exchangers are in thermal communication with a plurality electronic devices. Each of the plurality of heat exchangers includes at least one channel configured to receive and circulate a working liquid. Each of the plurality of heat exchangers may be a cold plate, an air cooler, and a combination thereof. The plurality of heat exchangers include at least one cold plate in direct contact with at least one of the plurality of electronic device. At least one air cooler circulates air and convectively absorbs heat from the remaining electronic devices.

### PRIORITY CLAIM AND CROSS-REFERENCE

This application claims the benefit of U.S. Provisional Application No. 62/741,819, filed Oct. 5, 2018, which application is expressly incorporated by reference herein in its entirety.

### FIELD OF THE INVENTION

The disclosure relates to systems and methods for cooling generally. More particularly, the disclosed subject matter relates to a system and a method for cooling electronic devices, while minimizing additional energy expenditure associated with the cooling system.

### BACKGROUND

Electronic devices inherently generate waste heat, which must be removed to prevent a run-away temperature rise and failure of the devices. Because the electronic devices generally have relatively low operating temperature limits (typically less than 80° C.) yet high heat fluxes (on the order of tens to hundreds of watts per square centimeter), the heat must be removed using low-temperature cooling means to facilitate the heat transfer (typically cooler than 20-50° C.). The waste heat is therefore rejected at the low temperatures of the cooling media, and thus is so degraded in energy quality, that the heat generally cannot be efficiently recovered for useful purposes.

Most electronic equipment, such as computers, telecommunications equipment, power conversion equipment, industrial lasers, radar systems, and military electronics, include systems that are assemblages of multiple and varied discrete devices. These devices such as power supplies, integrated circuit “chips,” memory storage devices, controllers, and the like, are housed in or on a common chassis or enclosure. Some constituent components may be amenable to direct conductive cooling, e.g., to heat sinks or direct-contact heat exchangers, while other components, due their complex shapes, can only be cooled indirectly by convection using air or another coolant gas or liquid.

Because of the impracticality of directly cooling compact electronics with ambient air or cooling water, intermediate cooling loops are often used to facilitate easy transport of the waste heat from the electronic devices to the final heat sink media. These intermediate loops consume additional power e.g., for pumps, blowers, refrigeration systems and the like, and add to the system complexity and cost. In addition, the intermediate cooling loops, having to operate at lower temperatures than the primary device coolers, further degrade the quality of the waste heat.

In facilities with multiple electronic equipment systems, such as data centers, telecommunication network hubs, military installations, and ships, the electronic equipment is often mounted, with chassis and enclosures, in racks or cabinets housed in common rooms. The aggregate heat rejected to the rooms often well exceeds the natural heat loss from the room walls, necessitating the need for auxiliary cooling systems, such as center room air handlers (CRAHs) and center room air conditioners (CRACs), to circulate the room air and remove the heat by secondary means. In some circumstances, some of auxiliary cooling can be accomplished by circulating a coolant liquid through heat exchangers in direct contact with the electronic components, and in turn, rejecting the heat to another cooling system.

Due to inherent inefficiencies and thermodynamic constraints, the additional power consumed by the auxiliary cooling systems is substantial, often in the order of 15-50% of the power used by the electronic devices themselves. Ultimately, the waste heat, along with additional heat generated by the auxiliary cooling systems, is rejected to the ambient air or cooling water.

Some vendors of electronics cooling equipment and enclosure have offered closed cabinets with recirculating indirect air cooling of the electronics, whereby fans or blowers force air across to convectively cool all the electronics, and the hot air exiting the electronics is cooled by an air-to-liquid heat exchanger and then recirculated back to the electronics. However, this approach is limited to relatively low heat loads because of the inefficient convective heat transfer between air and the electronics. Higher per-cabinet heat loads require that the recirculating air be chilled well below ambient temperatures, using power-intensive secondary cooling or refrigeration systems, therefore losing the advantage of low cooling power consumption and complexity. Because of the limited market potential due to the low power capacity limitations, several vendors of enclosed racks or cabinets with integrated water-to-air coolers, for example, Vertiv's LIEBERT® XDK-W and NVent's VARISTAR™ LHX series, no longer offer these systems for sale or have substantially de-rated the power heat removal capacities.

### SUMMARY

The present disclosure provides a system and a method for cooling heat-generating electronic devices and equipment. In such a system and a method, substantially all the heat dissipated from multiple electronic devices are removed and rejected remotely, with minimal additional power consumption.

Multiple electronics such as data servers, telecommunications equipment, and power conversion equipment, are housed in a common enclosure or cabinet, which is substantially sealed in some embodiments. The heat-generating electronic devices and components are cooled by a combination of direct-contact heat exchangers (“cold plates”) and indirect cooling via air recirculation through one or more heat exchangers (“air coolers”). The heat absorbed by the cold plates and the air coolers is transferred to a liquid or partially evaporated coolant fluid. The warmed liquid or vaporized coolant exiting the cold plates and the air coolers is transported to one or more external heat exchangers. The combined heat removed from the electronic devices is rejected to un-chilled or ambient cooling media. The heat-depleted cooled liquid or condensed evaporable coolant fluid is transported and recirculated to the cold plates and air coolers.

While the coolant may be any suitable single-phase or evaporable liquid, it is preferably a dielectric material, and most preferably a fluid, such as a refrigerant, whose normal boiling is below the temperature of the external heat exchanger cooling media, so that the coolant operates in the evaporating (2-phase) mode, at above-ambient pressures. Circulation of the coolant may be accomplished by active means, such as pumping, or preferably by passive means, such as natural circulation, thermosiphon action, or capillary action.

In accordance with some embodiments, the enclosure is provided with two or more parallel liquid-cooled or 2-phase (evaporatively) cooled heat exchangers operating in closed-loop circulation mode used to cool one or more electronic devices. At least one heat exchanger is a direct-contact cooler (“cold plate”) removing a portion of the heat from the electronics, and at least one heat exchanger is an air-to-coolant fluid unit (“air cooler”) used to remove the balance of the heat, by recirculating air that convectively cools and absorb the heat from the remaining heat-generating components. Preferably, the cold plates are use on the higher-heat-flux components, to minimize the heat load that is indirectly cooled by air convection. The heat absorbed by the one or more cold plates and the one or more air coolers is transferred to a single-phase liquid or an evaporating coolant flowing through the plates and/or coolers. The coolant fluid is transported to one or more heat exchangers external to the enclosure, wherein the heat is rejected to un-chilled cooling media such as ambient air or cooling water. The heat-depleted coolant is recirculated back to the cold plates and air coolers.

While any suitable single-phase or vaporizable coolant fluid may be used, for arrays of electronic devices that are in rooms or other enclosed spaces, particularly those frequented by people (e.g., in data centers), the coolant preferably has the following qualities, for compatibility with common heat exchanger and pump materials of construction, and to minimize the potential for harm in the event of a leak:

(1) Dielectric fluid (i.e., electrically non-conducting), so as to prevent electrical shocks and circuit damage,

(2) Normal boiling point below room temperature, which will evaporate into the air, rather than puddling on the electronic equipment,

(3) Non-toxic by inhalation or skin contact,

(4) Non-flammable at ambient temperatures, and

(5) Compatible with copper, aluminum, steel, and common elastomeric seal materials.

Coolants that meet these criteria include various refrigerants. When an refrigerant are used, it is preferred to select those that are environmentally benign, e.g., those with low ozone depletion potential and/or low global warming potential.

Circulation of the coolant fluid may be accomplished by passive means, such as natural circulation, thermosiphon action, or capillary action; or by active means, such as pumps. While passive circulation means are preferred, as they have no moving parts and consume no power, space constraints, mobile applications, or placement of the external heat exchanger relative to the cold plates and/or air coolers may require active circulation means.

The cold plates and air-coolers may be of any suitable design, including, but not limited to, tubes-in-plates, hollow blocks, mini- or microchannel heat exchangers, pin-fin heat exchangers, spray chambers, finned tubes, plate-fin exchangers, extruded microchannel sheets with or without surface enhancements, tubing coils, wire-and-tube coils, and any combinations thereof.

The external heat exchangers such as a cooling unit or a condenser, which may be of any suitable configuration, may be located in any external location relative to the electronics enclosure. If elevated above, cold plates and air coolers operate in the evaporative cooling mode. The condensed liquid coolant can be returned by gravity, obviating the need for pumps.

In accordance with some embodiments, a system is provided for cooling heat-generating electronic devices. The system comprises a plurality of heat exchangers in thermal communication with a plurality electronic devices. Each of the plurality of heat exchangers comprises at least one channel configured to receive and circulate a working liquid. Each of the plurality of heat exchangers is selected from the group consisting of a cold plate, an air cooler, and a combination thereof. The plurality of heat exchangers include at least one cold plate configured to contact at least one of the plurality of electronic device, and at least one air cooler configured to circulate air to and convectively absorb heat from one or more electronic devices.

In some embodiments, the plurality of heat exchangers and the plurality electronic devices are disposed in an enclosure. The plurality of heat exchangers are in a closed-loop circulation of the working fluid, and the at least one cold plate and at least one air cooler are connected in parallel. In some embodiments, the system is in a closed loop and the working fluid is in gravity-driven circulation. The system may also further comprise a pump configured to circulate the working liquid to the plurality of heat exchangers.

In some embodiments, the working liquid is configured to remain in liquid form. Each of the plurality of heat exchangers is configured to be liquid-cooled heat absorbers. The working liquid exits from the plurality of heat exchangers with a temperature increase. The system may further comprise a cooling unit configured to cool the working liquid from the plurality of heat exchangers so as to release heat. The system may also further comprises an expansion tank configured to provide additional volume to accommodate thermal expansion of the working liquid.

In some embodiments, the working liquid is evaporable and configured to become a first 2-phase mixture having a first liquid portion and a first vapor portion upon absorption of heat. The system may further comprise at least one condenser configured to condense the first vapor portion to a second liquid portion so as to release heat. The system may further comprise at least one vapor-liquid separator configured to feed the first liquid portion and/or the second liquid portion back to the plurality of heat exchangers.

In some embodiments, the working liquid is a refrigerant fluid, for example, comprising one or more hydrofluorocarbon or other materials as described herein.

In accordance with some embodiments, the present disclosure provides a system for cooling heat-generating electronic devices. Such a system comprises a plurality of heat exchangers in thermal communication with a plurality electronic devices disposed in an enclosure. Each of the plurality of heat exchangers comprises at least one channel configured to receive and circulate an evaporable working liquid. The working liquid is configured to become a first 2-phase mixture having a first liquid portion and a first vapor portion upon absorption of heat. Each of the plurality of heat exchangers is selected from the group consisting of a cold plate, an air cooler, and a combination thereof. The plurality of heat exchangers include at least one cold plate configured to contact at least one of the plurality of electronic device, and at least one air cooler configured to circulate air to and convectively absorb heat from one or more electronic devices. The plurality of heat exchangers are in a closed-loop circulation of the working fluid, and the at least one cold plate and at least one air cooler are connected in parallel.

In some embodiments, the at least one cold plate includes a plurality of code plates connected in parallel. The system may further comprise at least one condenser configured to condense the first vapor portion to a second liquid portion so as to release heat. In addition, the system may further comprise at least one vapor-liquid separator configured to feed the first liquid portion back to the plurality of heat exchangers.

In another aspect, the present disclosure also provides a method for cooling heat-generating electronic devices using the system as described herein. Such a method comprises providing the working liquid to the plurality of heat exchangers to absorb heat generated by the plurality electronic devices, supplying the working liquid exiting from the plurality of heat exchangers to a cooling unit or a condenser so as to release the heat, and recirculating the working liquid from the cooling unit or the condenser back to the plurality of heat exchangers.

In some embodiments, the working liquid exiting from at least one of the plurality of heat exchanger remains in liquid form, and is cooled by the cooling unit. In some embodiments, the working liquid exiting from at least one of the plurality of heat exchangers becomes a first 2-phase mixture having a first liquid portion and a first vapor portion upon absorption of heat. The method may further comprise condensing the first vapor portion to a second liquid using the condenser; and feeding the first liquid portion and/or the second liquid portion back to the plurality of heat absorption devices from at least one vapor-liquid separator.

In some embodiments, the system is in a closed loop and the working fluid is in gravity-driven circulation, or driven using a pump. The working fluid is a refrigerant fluid comprising one or more hydrofluorocarbon or other materials as described herein.

The advantage of the system provided in the present disclosure is that it facilitates the removal of substantially all of the heat generated by the enclosed electronics without requiring power- and capital-intensive auxiliary or secondary cooling systems, while allowing both higher power densities and more efficient heat transfer than conventional cooling methods.

Furthermore, in facilities such as data and telecommunications centers, self-contained cooling cabinets may be used to house the electronics. The system described in the present disclosure allows closer spacing of the equipment (less floor space) than conventional open-rack systems.

The system in the present disclosure, particularly with the passive-circulation evaporating-coolant configurations, also allows installation of the equipment in unconventional and difficult-to-service installations, such as underground, submerged, or tower-mounted locations as the absence of moving parts allows unattended and/or remote operation with minimal likelihood of requiring on-site maintenance of the cooling system.

In addition to reducing operating and capital costs, the systems in the present disclosure are also more compact and environmentally beneficial (“green”), as the systems minimize the power required for cooling, reducing the energy (including conversion inefficiencies) that would otherwise be required to remove a corresponding heat load.

### BRIEF DESCRIPTION OF THE DRAWINGS

The present disclosure is best understood from the following detailed description when read in conjunction with the accompanying drawings. It is emphasized that, according to common practice, the various features of the drawings are not necessarily to scale. On the contrary, the dimensions of the various features are arbitrarily expanded or reduced for clarity. Like reference numerals denote like features throughout specification and drawings. The exemplary figures illustrate the heat absorption devices as being in direct thermal contact with the heat-generating electronics, thereby transferring the heat directly to the heat absorption device (evaporator). However, it is further understood that alternatively, the heat from the heat generating electronics may be transferred indirectly to the heat absorption device, e.g. via air circulated between an air-cooled heat sink in direct thermal contact with the heat-generating electronics, and air-fluid heat exchanger (radiator) containing the refrigerant, thereby serving as the heat absorption device.

FIG. 1 illustrates an exemplary electronic equipment system such as a data server.

FIG. 2 illustrates a system with an air-cooling arrangement configured to cool a room including multiple electronic systems.

FIG. 3 illustrates a first exemplary system, which is for direct liquid-phase (DL) cooling of electronic devices, in some embodiments.

FIG. 4 illustrates a second exemplary system, which is for direct 2-phase (D2P) cooling of electronic devices, in accordance with some embodiments.

FIG. 5 illustrates a third exemplary system, which is for direct 2-phase (D2P) cooling electronic devices, in accordance with some embodiments.

FIG. 6 illustrates a fourth exemplary system, which is for indirect liquid-phase (IL) cooling of electronic devices, in accordance with some embodiments.

FIG. 7 illustrates a fifth exemplary system, which is for indirect 2-phase (I2P) cooling electronic devices, in accordance with some embodiments.

FIG. 8 illustrates a sixth exemplary system, which is for indirect 2-phase (I2P) cooling of electronic devices, in accordance with some embodiments.

FIG. 9 illustrates a seventh exemplary system, which is for hybrid liquid-phase (HL) cooling electronic devices, in accordance with some embodiments.

FIG. 10 illustrates an eighth exemplary system, which is for hybrid 2-phase (H2P) cooling of electronic devices, in accordance with some embodiments.

FIG. 11 illustrates a ninth exemplary system, which is for hybrid 2-phase cooling (H2P) electronic devices, in accordance with some embodiments.

FIG. 12 is a flow diagram illustrating an exemplary method in accordance with some embodiments.

FIGS. 13A and 13B illustrate two series thermal resistance models for cooling of process chips using cold plate and air-cooled heat sink, respectively.

### DETAILED DESCRIPTION

This description of the exemplary embodiments is intended to be read in connection with the accompanying drawings, which are to be considered part of the entire written description. In the description, relative terms such as “lower,” “upper,” “horizontal,” “vertical,”, “above,” “below,” “up,” “down,” “top” and “bottom” as well as derivative thereof (e.g., “horizontally,” “downwardly,” “upwardly,” etc.) should be construed to refer to the orientation as then described or as shown in the drawing under discussion. These relative terms are for convenience of description and do not require that the apparatus be constructed or operated in a particular orientation. Terms concerning attachments, coupling and the like, such as “connected” refer to a relationship wherein structures are secured or attached to one another either directly or indirectly through intervening structures, as well as both movable or rigid attachments or relationships, unless expressly described otherwise.

For purposes of the description hereinafter, it is to be understood that the embodiments described below may assume alternative variations and embodiments. It is also to be understood that the specific articles, compositions, and/or processes described herein are exemplary and should not be considered as limiting.

In the present disclosure the singular forms “a,” “an,” and “the” include the plural reference, and reference to a particular numerical value includes at least that particular value, unless the context clearly indicates otherwise. Thus, for example, a reference to “a cold plate” is a reference to one or more of such structures and equivalents thereof known to those skilled in the art, and so forth. When values are expressed as approximations, by use of the antecedent “about,” it will be understood that the particular value forms another embodiment. As used herein, “about X” (where X is a numerical value) preferably refers to ±10% of the recited value, inclusive. For example, the phrase “about 8” preferably refers to a value of 7.2 to 8.8, inclusive; as another example, the phrase “about 8%” preferably (but not always) refers to a value of 7.2% to 8.8%, inclusive. Where present, all ranges are inclusive and combinable. For example, when a range of “1 to 5” is recited, the recited range should be construed as including ranges “1 to 4”, “1 to 3”, “1-2”, “1-2 & 4-5”, “1-3 & 5”, “2-5”, and the like. In addition, when a list of alternatives is positively provided, such listing can be interpreted to mean that any of the alternatives may be excluded, e.g., by a negative limitation in the claims. For example, when a range of “1 to 5” is recited, the recited range may be construed as including situations whereby any of 1, 2, 3, 4, or 5 are negatively excluded; thus, a recitation of “1 to 5” may be construed as “1 and 3-5, but not 2”, or simply “wherein 2 is not included.” It is intended that any component, element, attribute, or step that is positively recited herein may be explicitly excluded in the claims, whether such components, elements, attributes, or steps are listed as alternatives or whether they are recited in isolation.

Because of the problems described in the Background, it is desirable to cool the electronic systems in-situ and reject the heat directly to the final external cooling media such as ambient air or cooling water, avoiding the need for intermediate cooling loops and their associated additional equipment and power consumption.

One approach is to cool the electronics with direct-contact heat exchangers (“cold plates”) cooled with recirculating un-chilled liquids such as water and dielectric oil, which are in turn cooled externally by ambient air or cooling water. However, as described above, direct-contact cooling is not practical for all the heat-generating components in electronic systems. For example, in data servers and telecommunications network switches, typically less than 70% of the heat is generated by components (e.g., electronic chips) that are amenable to direct-contact cooling. The remainder of the heat must be removed by indirect convective cooling.

With single-phase liquid or gas cooling, the heat is removed by the so-called “sensible heating” of the liquid, i.e., relying on the heat capacity of the fluid whose exiting temperature increases in proportion to the heat absorbed. Thus, single-phase cooling is inherently non-isothermal, and the device operating temperatures increase with increasing fluid exiting temperatures. The fluid temperature rise can be reduced, but not eliminated, by increasing the circulation rate of the fluid, which in turns consumes more pumping or fan power and requires a physically larger pump or fan.

In 2-phase cooling systems used for cooling electronics in some embodiments, the devices are cooled, either directly or indirectly, by evaporating a working fluid, which can afterwards be condensed and re-used. Evaporative cooling relies on the boiling mode, and has the advantages of higher heat transfer coefficients for better heat transfer per unit of fluid flow rate of the coolant fluid. Evaporative cooling is isothermal, with a substantially constant temperature across the heat exchanger, irrespective of heat load. Evaporative cooling also requires much less coolant flow. The majority of heat is latent heat absorbed through vaporization of the boiling fluid, rather than the sensible heat (heat capacity) of a single-phase liquid or gas. 2-phase cooling means include wick-type heat pipes, loop heat pipes, evaporative spray cooling, evaporative immersion cooling, the like and the combinations thereof. The circulation of the evaporable working fluid may be active, for example, driven by pumps, or passive, e.g., driven by natural convection (thermosiphon principle) or capillary flow. However, 2-phase direct-contact cooling has the same limitations as direct-contact liquid cooling, in terms of its impracticality to remove heat from components that can only be cooled convectively.

Therefore, there is a need and a market for a system and a method for simultaneously handling high heat loads per unit area or volume occupied by multiple electronic systems, and rejecting substantially all of the heat directly to the final external cooling media such as ambient air or cooling water while minimizing the power consumption and size of equipment associated with the cooling systems. It is also desirable to easily transport the absorbed heat and reject it remotely, to minimize the size and infrastructure associated with the relatively costly spaces where the electronics are housed.

The present disclosure provides a system and a method for cooling heat-generating electronic devices and equipment.

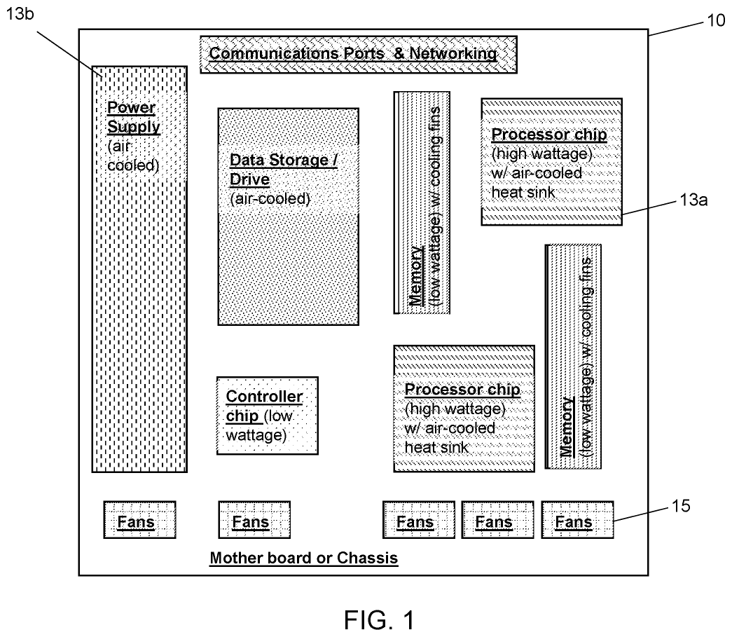

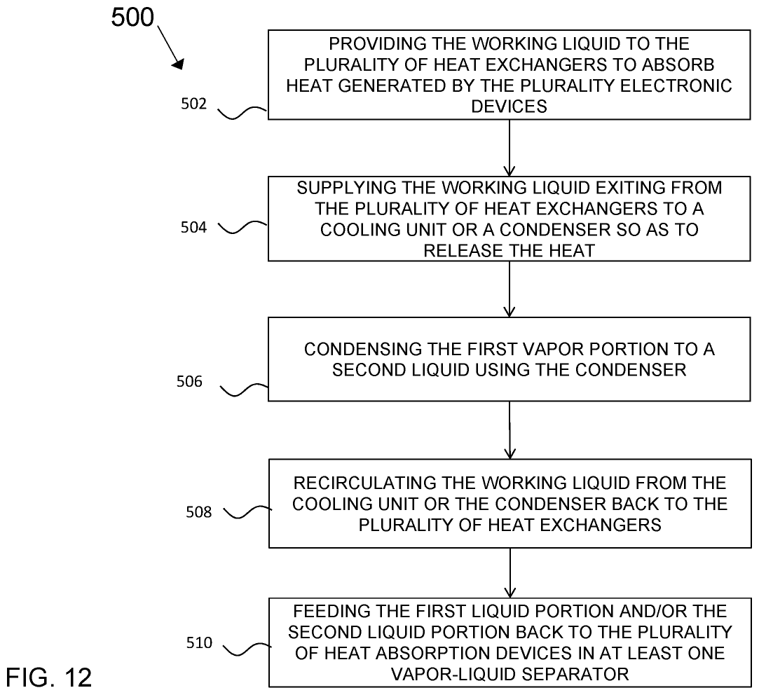

In FIGS. 1-13, like items are indicated by like reference numerals, and for brevity, descriptions of the structure, provided above with reference to the preceding figures, are not repeated. The method described in FIG. 12 is described with reference to the exemplary structure described in FIGS. 1-11. Unless indicated otherwise, the components in FIGS. 1-11 and 13 may be aligned horizontally or vertically, at different heights.

Examples of the electronic equipment include, but are not limited to, information technology components, such as those used in data centers; and telecommunication technology components, such as network switches, modems, multiplexers, mobile phone signal boosting equipment and the like. The electronic equipment may also include power conversion, management, or distribution equipment such as integrated gate bipolar transistors (IGBTs), transformers, power supply units, voltage regulation modules, variable-speed motor drives, regenerative braking systems, photovoltaic cells, the like and the combinations thereof.

One or more heat-generating electronic device and equipment may include at least one component that can be conductively cooled by direct-contact cooling means, and at least one component that can only be cooled convectively by air cooling. The heat-generating electronic devices and equipment may be housed in an enclosure or cabinet, which may be substantially sealed, and may optionally include an entrance, an opening, or a door.

The enclosure is provided with two or more parallel heat exchangers operating in closed-loop circulation of a coolant fluid. A heat exchanger is also referred as a heat absorption device. At least one heat exchanger is a direct-contact cooler (“cold plate”) removing a portion of the heat from the electronics, and at least one heat exchanger is an air-to-coolant unit (“air cooler”) used to remove the balance of the heat, by recirculating air that convectively cools and absorbs the heat from the remaining heat-generating components.

The coolant carrying the heat absorbed by the one or more cold plates and the one or more air coolers is transported outside of the enclosure to one or more heat exchangers external to the electronics enclosure. The heat is rejected from the coolant to un-chilled cooling media such as ambient air or cooling water. The heat-depleted coolant is transported back to the one or more cold plates and one or more air coolers inside the enclosure.

The cold plates and air-coolers may be of any suitable design, including, but not limited to, tubes-in-plates, hollow blocks, mini- or microchannel heat exchangers, pin-fin heat exchangers, spray chambers, finned tubes, plate-fin exchangers, extruded microchannel sheets with or without surface enhancements, tubing coils, wire-and-tube coils, and any combination thereof.

The external heat exchangers, which may be of any suitable configuration, may be located in any external location relative to the enclosure housing the electronic devices and equipment. In some embodiments, if elevated above, cold plates and air coolers operating in the evaporative cooling mode, the condensed liquid coolant can be returned by gravity, obviating the need for pumps.

In some embodiments, the coolant (i.e., the working liquid) is a vaporizable fluid. The one or more cold plates and the one or more air coolers operate as evaporators. The entering coolant is a liquid or two-phase mixture of liquid and vapor, and the exiting coolant is a two-phase mixture with a higher vapor fraction than the entering coolant.

In some embodiments, the coolant is a liquid, and the one or more cold plates and the one or more air coolers operate as liquid-cooled heat absorbers. The entering coolant is at a lower temperature than the exiting coolant.

The coolant circulation may be optionally driven by active means, such as one or more pumps. In some embodiments, the coolant circulation is driven by passive means, such as density differences, buoyancy, thermosiphon principle, or capillary action. The coolant may be circulated passively by liquid/vapor density differences and gravity return of the liquid phase (thermosiphon circulation). The external heat exchanger is elevated above a vapor-liquid separator vessel, which in turn is elevated at a certain height above both the highest cold plate and above the exit of the air cooler(s).

Any suitable vaporizable fluid may be used. In some preferred embodiments, for arrays of electronic devices that are in rooms or other enclosed spaces, particularly those visited by people (e.g., in data centers), the evaporative working fluid preferably has the following qualities, for compatibility with common heat exchanger and pump materials of construction, and minimization in the potential for harm in the event of a leak:

(1) Dielectric fluid (i.e., electrically non-conducting), so as to prevent electrical shocks and circuit damage,

(2) Normal boiling point below room temperature, which will evaporate into the air, rather than puddling on the electronic equipment,

(3) Non-toxic by inhalation or skin contact,

(4) Non-flammable at ambient temperatures inside the electronics enclosure or the external ambient air temperatures,

(5) Not freeze at low (e.g., wintertime) external ambient temperatures, and

(7) Compatible with copper, aluminum, steel, and elastomeric seal materials.

When the coolant is a liquid, it is understood that the coolant loop operates at a pressure above the vapor pressure of the coolant at the highest temperature in the circulation loop.

Coolants that meet these criteria include various refrigerants and refrigerant mixtures. It is preferable to employ refrigerants which are environmentally benign, i.e., having relatively low ozone-depletion potential (ODP) and/or low global warming potential (GWP). In some embodiments, refrigerant fluids or refrigerant fluid mixtures may be used. Examples of refrigerant-type coolants having zero ozone-depletion potential (ODP) include, but are not limited to, hydrofluorocarbons such as R-32, R-125, R-134a, R-143a, R-152a, R-245fa, R-404a, R-407a, R-407c, R-507, and combinations thereof. Examples of refrigerant-type coolants having low ODP and low global warming potential (GWP<5) include, but are not limited to, carbon dioxide, and hydrofluoroolefins such as R-1224ze, R1233zd, R-1234ze, R-1234yf, and combinations thereof.

It is to be understood that other aspects of the present disclosure will become readily apparent to those skilled in the art from the following detailed description, and various embodiments of the invention are shown and described by way of illustration. The present disclosure is capable for other and different embodiments, and its several details are capable of modification in various other respects, without departing from the spirit and scope of the present disclosure.

Accordingly, the drawings and detailed description are to be regarded as illustrative in nature and not as restrictive. While the figures refer to “cold plates” which are heat absorption devices in direct thermal contact with the electronics, it is understood that alternatively, the cold plates may be substituted with air-cooled heat sinks and air-heated evaporators (radiators), wherein the heat from the electronics is transferred (indirectly) by the warmed air to one or more evaporators, which in turn cool the air. The air can be recirculated back to the heat sinks.

In FIGS. 1-11, unless indicated otherwise, the components in the systems are in thermal communication with each other, and may be fluidly connected with each other if needed. As shown in arrowed lines, the fluids and vapors are transported in pipes. For illustration purposes, the fluids are shown in solid arrowed lines while the vapors are shown in dashed arrowed lines.

The plurality of heat absorption devices (or heat exchangers) such as cold plates and/or radiators are in thermal communication with a plurality electronic devices, for example, devices in a data center. Each of the plurality of heat absorption devices includes at least one channel configured to receive and circulate an evaporable working liquid (e.g., a refrigerant). The term “in thermal communication with” used herein may be understood that the components are “in proximity to or in contact with” each other to thermally interact with each other.

FIG. 1 schematically illustrates an exemplary electronic equipment system 10, for example, a data server. Such an electronic equipment system 10 is an assembly including various components or devices 13. For example, these devices 13 include high-heat-intensity devices 13a (e.g., processor chips), low-intensity chips (e.g., controller and memory), and others devices 13b that can only be convectively cooled (e.g., power supply, data storage drive, communications ports). As illustrated in FIG. 1, the system 10 is provided with multiple on-board fans 15 to direct localized cooling air to the various devices 13.

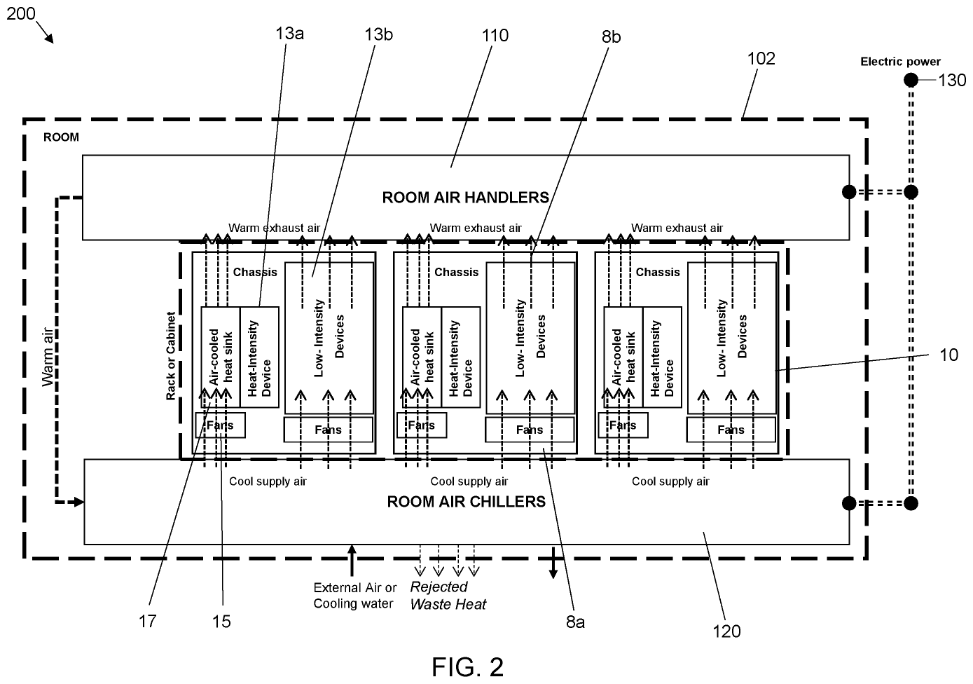

FIG. 2 illustrates a system 200 with an air-cooling arrangement to cool a room 102 containing multiple electronic systems 10, which may include high heat-intensity devices 13a, low heat-intensity devices 13b, fans 15, and air-cooled heat sink 17. The system 200 may include at least one air handler 110 and at least one air chiller 120, which are connected with an electric power source 130. Because of the high-intensity components, the air 8a must be chilled. The warm air 8b exhausted to the room 110 is recirculated though by an air handler 110 through the chiller 120 where the air 8b is cooled to sub-ambient temperatures before entering the electronics systems 10. The heat is ultimately exhausted to the environment by ambient air or water cooling of the chillers 120, which may be handled by additional auxiliary systems (not shown).

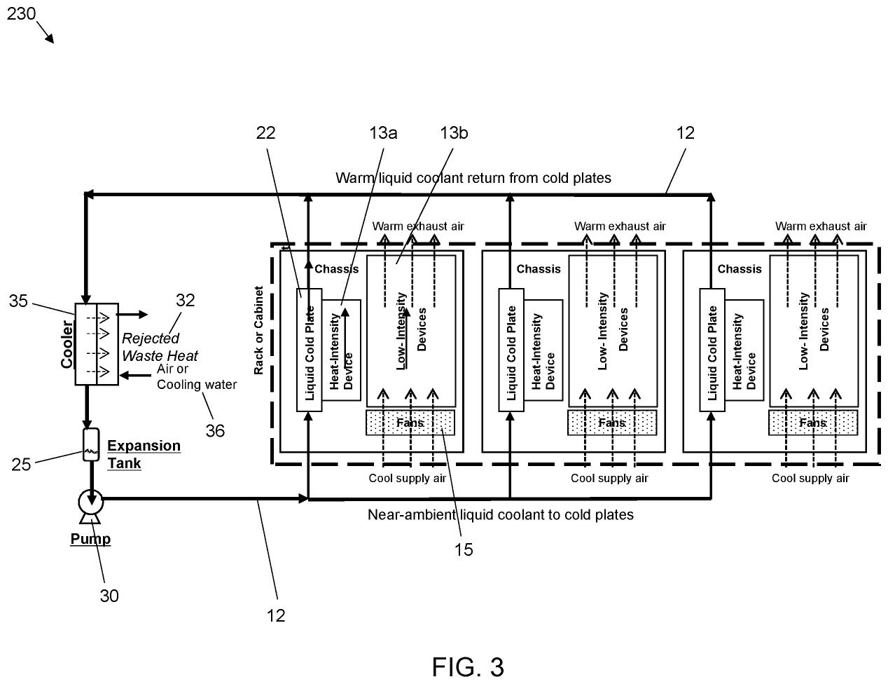

Referring to FIG. 3, in some embodiments, a first exemplary system 230 is used for direct liquid-phase (DL) cooling of electronic devices, including high heat-intensity electronic devices 13a in a room. Direct cooling is achieved through conduction by supplying a working liquid 12 to at least one cold plate 22, which is in contact with and absorbs heat from the high heat-intensity electronic devices 13a. The remaining components including low heat-intensity devices 13b are cooled using chilled air as described in FIG. 2. Air handlers 110 and chillers 120 as described in FIG. 2 can be also used. The heat 32 is rejected directly from the working liquid 12 (i.e., coolant) to the environment by a cooling media such as ambient air or water 36 from a cooling unit 35. The cooling unit 35 is also referred as a cooler or an external heat exchanger, and is used to cool the liquid 12 or condense the vaporized coolant if needed. An expansion tank 25 and a pump 30 may be optionally used. The expansion tank 25 is configured to provide additional volume and accommodate changes in the liquid density (volume) as the coolant temperatures may vary. The pump 30 is configured to circulate the working liquid 12 to the cold plates 22 in the closed loop as shown in FIG. 3. In some embodiments, a plurality of cold plates 22 may be used, and may be connected in parallel.

For the purpose of illustration, in FIGS. 3-11, the heat 32 is rejected to un-chilled and/or ambient cooling media. In some embodiments, the heat is rejected to ambient cooling media 36 such as water and/or air. The term “un-chilled” used herein is understood that the cooling media 36 is not cooled by any external or supplemental refrigerating equipment or mechanical cooling means, and the cooling media 36 can be at any outdoor ambient temperature.

Reference to the term “in parallel” used in the present disclosure refers to a configuration of the cold plates 22 with respect to the flow direction of the working liquid 12, and is compared to the term “in series.” A plurality of cold plates 22 connected in parallel may or may not be geometrically parallel to each other.

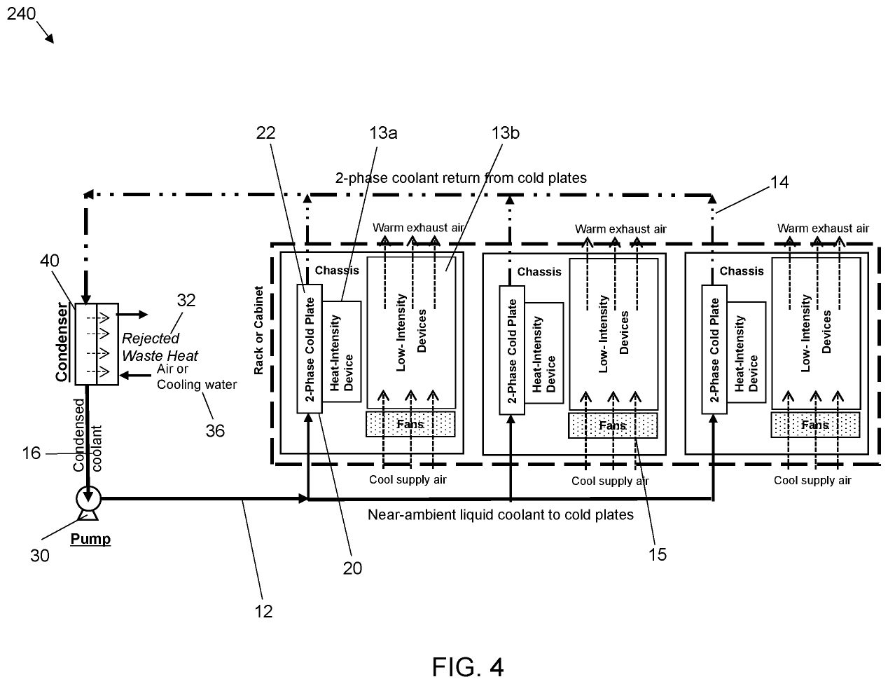

Referring to FIG. 4, in some embodiments, a second exemplary system 240 is used for direct 2-phase (D2P) cooling of electronic devices. The second exemplary system 240 is the same as the first exemplary system 130, except that an evaporable working liquid 12 (i.e., evaporable coolant) and a condenser 40 are used. The working liquid 12 is configured to become a first 2-phase mixture 14 having a liquid portion and a vapor portion upon absorption (either directly or indirectly) of heat. The 2-phase mixtures 13 from the cold plates 22 are sent to the condenser 40, where the vapor portion of the coolant 12 condenses and combines with the liquid portion. The condensed working liquid 16 is then pumped back to the cold plates 22. A reservoir or expansion tank (not shown) may be used.

The working liquids 12, 14, and 16 at different stages in this disclosure may have the same compositions, and the reference numerals 12, 14, and 16 may be used interchangeably.

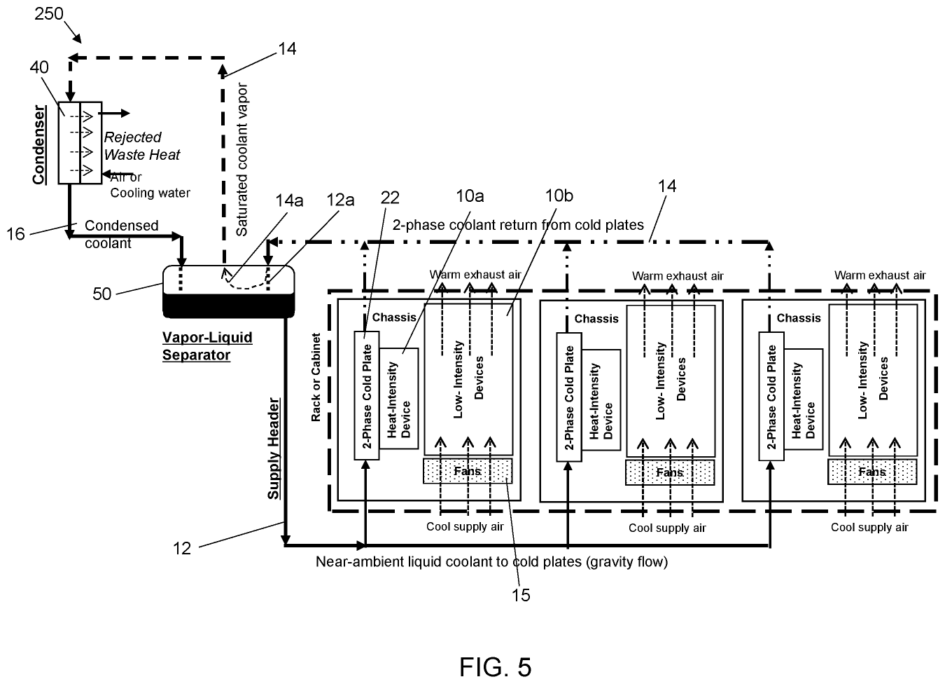

Referring to FIG. 5, in some embodiments, a third exemplary system 250 is for direct 2-phase (D2P) cooling electronic devices. The third exemplary system 250 is the same as the second exemplary system 240 in FIG. 4, except that no pump 30 is used and a vapor liquid separator 50 is used. As shown in FIG. 5, an evaporable working liquid (i.e., coolant) 12 is used in the cold plates 22, with passive circulation based on thermosiphon principle. Liquid coolant 12 is supplied to the cold plates 22 by gravity. A 2-phase mixture 14 having a first liquid portion 12a and a first vapor portion 14a is formed upon absorption of heat. The 2-phase mixture 14 from each cold plate 22 is supplied to the separator 50, where the vapor portion 14a is sent to a condenser 40. The condensed coolant returns by gravity to the separator 50 and combined with the liquid portion 12a from the 2-phase mixtures 14 before returning by gravity to the cold plates 22. In some embodiments, supplemental (air) cooling may be needed in the exemplary system 250, unless cold plates 22 cover all server components such as RAM, power supply, hard drives, controller chips, and networking components.

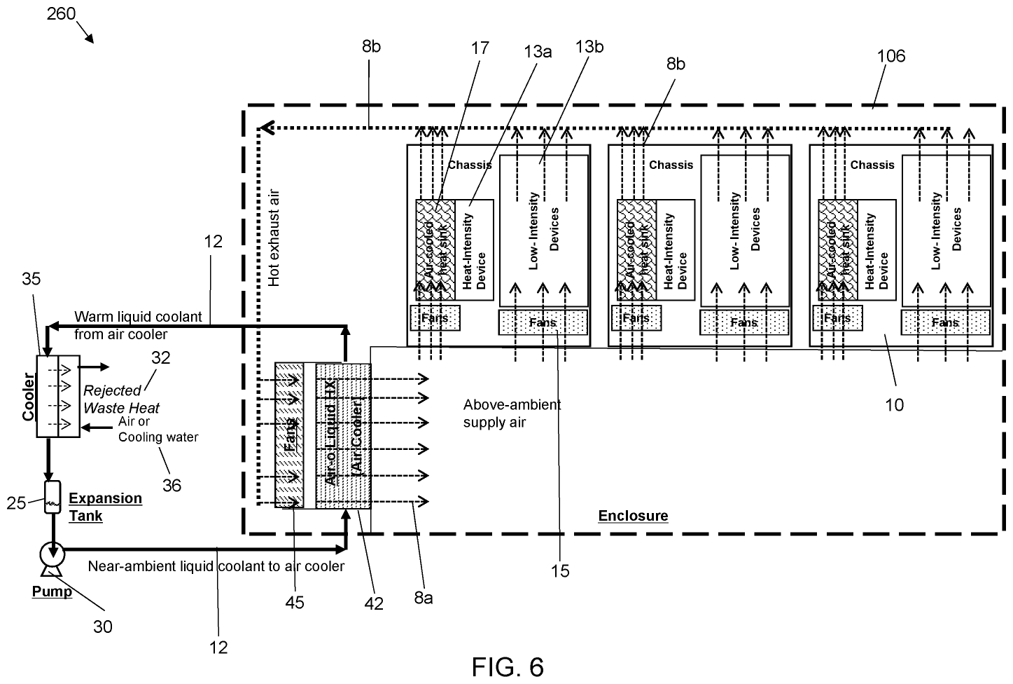

FIGS. 6-8 schematically depict various configurations for indirect cooling and remotely rejecting all the heat from all the electronic components in a self-contained and substantially sealed enclosure 106 containing multiple electronic systems 10. Sometimes a room may contain multiple such enclosures 106. At least one liquid- or 2-phase-cooled heat exchanger (“air cooler” or “radiator”) 42 is used to generate cooled air 8a, while heat is transferred to the coolant 12. Heated air 8b exiting the various electronic systems 10 is recirculated by fans or blowers 15, 45 in the enclosure 106. The coolant 12 is transported to an external heat exchanger 35 or 40, rejecting the heat 32 directly from the coolant 12 to the environment by a cooling media such as ambient air or water 36 from the external heat exchangers. The coolant 12 exits the external heat exchanger 25 or 40 near, but slightly above the temperature of the ambient air or cooling water media. The near-ambient-temperature coolant 12 returns to the air cooler 42, where it cools warm exhaust air 8b from the electronic systems 10 via the air cooler 42. The air 8a exits the air cooler 42, above the external ambient air or water cooling media temperature, and becomes the supply air 8a for cooling the electronic systems.

Referring to FIG. 6, in some embodiments, a fourth exemplary system 260, is used for indirect liquid-phase (IL) cooling of electronic devices and equipment. The air cooler 42 is cooled with pumped liquid coolant 12, similar to the configuration used for the cold plates 22 as described in FIG. 3. An expansion tank 25, a pump 30, and an external cooler 35 may be used as described in FIG. 3. As shown in FIG. 6, air cooler 42 is inside the enclosure 106 and provides cool air in the fully-contained air circulation, thus cooling all the electronic systems 10 inside the enclosure 106. The heat 32 from the electronic systems 10 are rejected outside the enclosure 106.

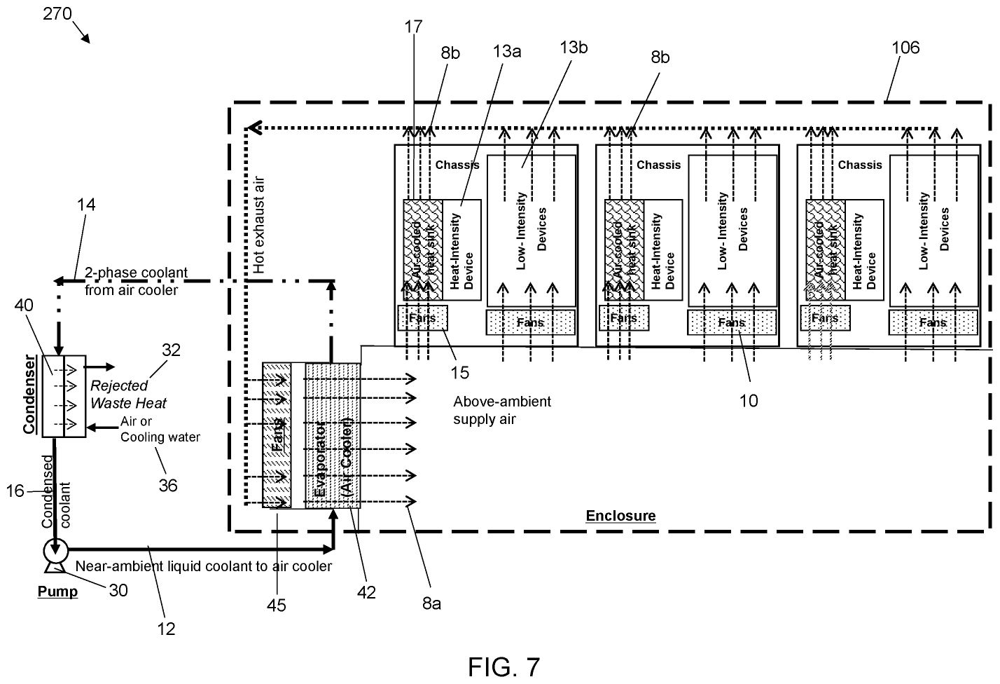

Referring to FIG. 7, in some embodiments, a fifth exemplary system 270 is used for indirect 2-phase (I2P) cooling electronic devices and equipment. Exemplary system 270 is similar to exemplary system 260, except that a 2-phase evaporable coolant 12 is used in air cooler 42. As such, a condenser 40 is used as described in FIG. 4. A pump 30 may be used. An expansion tank 25 may not be needed. As shown in FIG. 7, air cooler 42 is inside the enclosure 106 and provides cool air in the fully-contained air circulation, thus cooling all the electronic systems 10 inside the enclosure 106. The heat from the electronic systems 10 are rejected outside the enclosure 106.

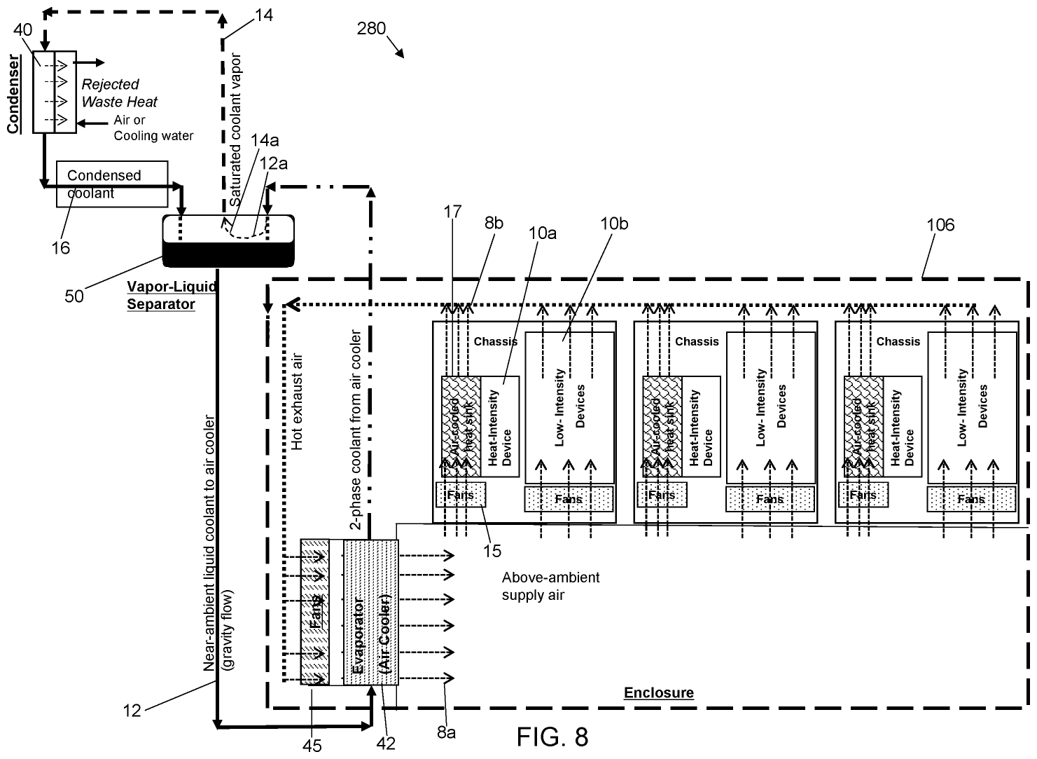

Referring to FIG. 8, in some embodiments, a sixth exemplary system 280 is used for indirect 2-phase (I2P) cooling of electronic devices and equipment. As shown in FIG. 8, the components inside the enclosure 106 are the same as those described in FIG. 7, while the components outside the enclosure 106 are the same as those described in FIG. 5. A 2-phase evaporable coolant 12 is used in the air cooler 42, with passive circulation of the coolant 12 and its 2-phase mixture 14 based on the thermosiphon principle. As described in FIG. 5, vapor-liquid separator 50 may be used.

Because of the above-ambient recirculating supply air temperatures in the exemplary systems of FIGS. 6-8, the electronic systems 10 may operate at higher temperatures, compared to the system of FIG. 2. Additionally because of the limited heat capacity of air compared to the working liquid or evaporable coolant, the enclosed indirect air cooling as shown in FIGS. 6-8 is limited to electronic systems having relatively low power densities. For example, when the electronic systems 10 are data servers and the enclosure 106 is a server cabinet, the indirect cooling system can handle a maximum of 3-8 kW heat load per cabinet.

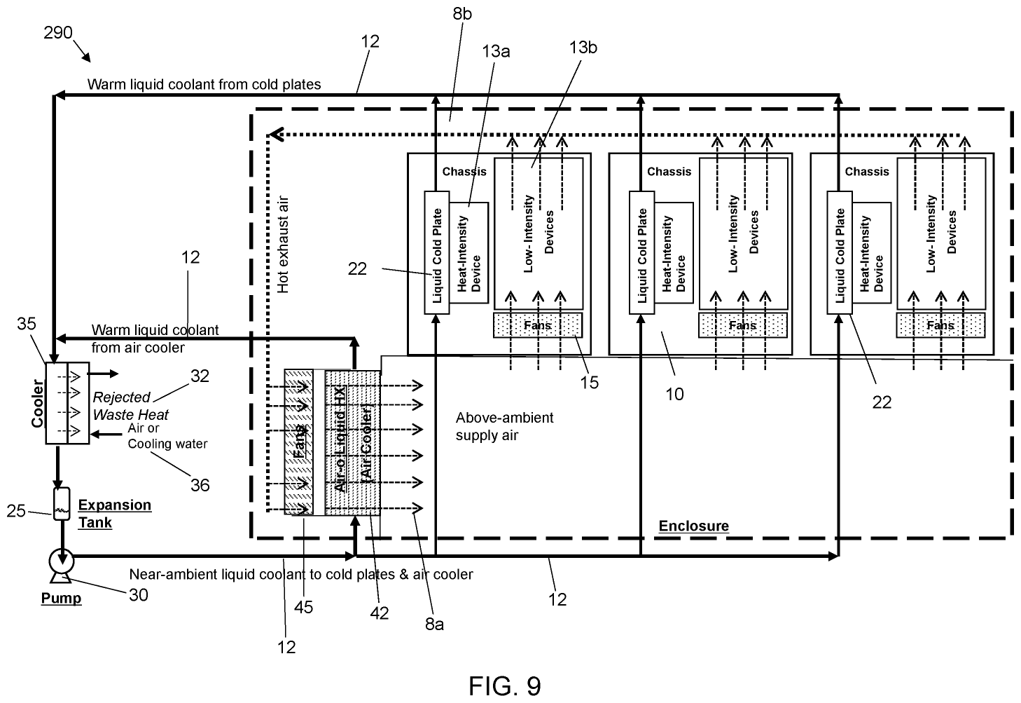

FIGS. 9-11 illustrate exemplary systems in accordance with some embodiments. Such exemplary systems are used for “hybrid” combined direct and indirect cooling, remotely rejecting substantially all the heat from the multiple heat-generating electronic systems 10 housed in a self-contained substantially sealed enclosure. Sometimes a room may contain multiple such enclosures. As described in FIGS. 3-5, high-intensity electronic components 13a are directly cooled by conduction to cold plates 22. As described in FIGS. 6-8, the remaining components 13b are convectively cooled by air recirculated by fans or blowers through air coolers 42. The heat 32 is rejected directly from the coolant 12 to the environment via ambient air or cooling water 36, by the external heat exchangers (or cooler) 35 used to cool the liquid 12 or condense the vaporized coolant 14.

Referring to FIG. 9, in some embodiments, a seventh exemplary system 290 is used for hybrid liquid-phase (HL) cooling electronic devices and equipment. The cold plates 22 and the air cooler 42 are cooled with pumped liquid coolant 12, similar to the configuration used for the cold plates 22 in FIG. 3 and the air cooler 42 in FIG. 6. The cold plates 22 may be inside servers. As shown in FIG. 9, cold plates 22 and air cooler 42 are inside the enclosure 106, and provide cool air in the fully-contained air circulation, thus cooling all the electronic systems 10 inside the enclosure 106. The heat 32 from the electronic systems 10 are rejected outside the enclosure 106. Exemplary system 290 is suitable for cooling electronic systems 10 having higher heat loads and circuit density than the systems for indirect cooling as described in FIGS. 6-8. Directly-cooled devices 13a may have lower internal operating (junction) temperatures than that with indirect/air cooling at a given working fluid temperature.

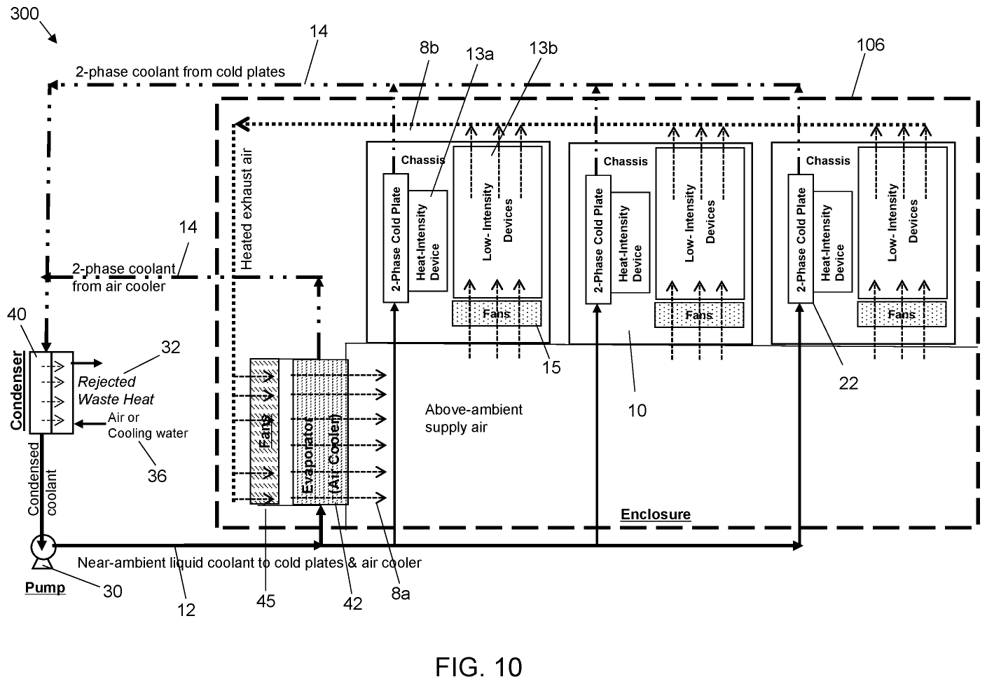

Referring to FIG. 10, in some embodiments, an eighth exemplary system 300 is used for hybrid 2-phase (H2P) cooling of electronic devices and equipment. System 300 is similar to the exemplary system 290, except that a 2-phase evaporable coolant 12 is used in the cold plates 22 and the air cooler 42, with pumped circulation of the coolant 12. Thus a condenser 40 is used and an expansion tank 25 is not used in some embodiments as described in FIGS. 4 and 7. As shown in FIG. 10, cold plates 22 and air cooler 42 are inside the enclosure 106, and provide cool air in the fully-contained air circulation, thus cooling all the electronic systems 10 inside the enclosure 106. The heat from the electronic systems 10 are rejected outside the enclosure 106. Exemplary system 300 is suitable for cooling electronic systems 10 having higher heat loads and circuit density than the systems for indirect cooling as described in FIGS. 6-8. Directly-cooled devices 13a may have lower internal operating (junction) temperatures than that with indirect/air cooling at a given working fluid temperature.

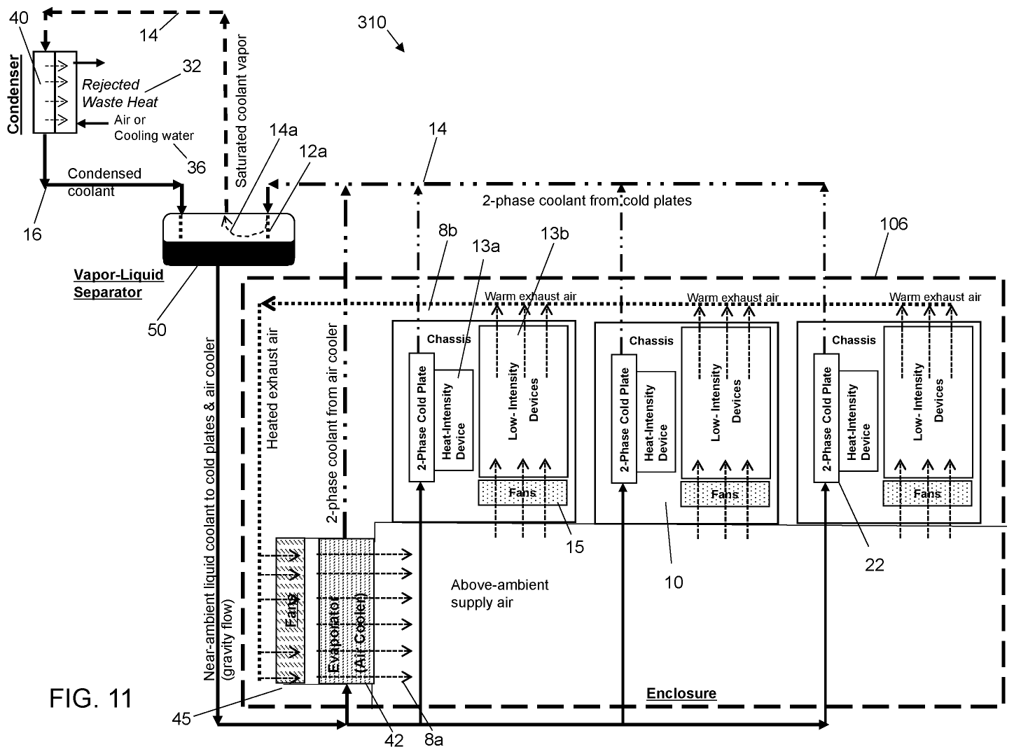

Referring to FIG. 11, in some embodiments, a ninth exemplary system 31 is for hybrid 2-phase cooling (H2P) electronic devices and equipment. The configuration inside the enclosure 106 is the same as that described in FIG. 10. The components outside the enclosure 106 are the same as those described in FIGS. 5 and 8. A 2-phase evaporable coolant 12 is used in the cold plates 22 and the air cooler 42, with passive circulation of the coolant 12 based on thermosiphon principle. A vapor-liquid separator 50 is used as described in FIGS. 5 and 8.

Referring to FIG. 12, the present disclosure also provides an exemplary method 500 in accordance with some embodiments. The exemplary method 500 is a method for cooling heat-generating electronic devices using the system as described herein using each of the exemplary systems described above.

At step 502, the working liquid 12 is provided to the plurality of heat exchangers 20 (also referred as “heat absorption devices”) to absorb heat generated by the plurality electronic systems 10 including devices and equipment. The plurality of heat exchangers 20 include cold plates 22 and/or air cooler 42. The working liquid 12 may remain in liquid form or becomes a 2-phase mixture.

At step 504, the working liquid 12 (or 14) exiting from the plurality of heat exchangers 20 is supplied to a cooling unit 35 or a condenser 40 so as to release the heat. The heat is rejected to un-chilled and/or ambient cooling media. In some embodiments, the heat is rejected to ambient cooling media such as water and/or air. The term “un-chilled” used herein is understood that the cooling media 36 (FIGS. 3-11) is not cooled by any external or supplemental refrigerating equipment or mechanical cooling means, and the cooling media 36 can be at outdoor ambient temperature.

In some embodiments, the working liquid 12 exiting from at least one of the plurality of heat exchanger 20 remains in liquid form, and is cooled by the cooling unit 35 as described above.

In some embodiments, the working liquid 12 exiting from at least one of the plurality of heat exchangers 20 becomes a 2-phase mixture 14 having a liquid portion 12a and a vapor portion 14a upon absorption of heat. The method 500 may include step 506.

At step 506, the vapor portion 14a is condensed to a second liquid portion 16 using the condenser 40.

At step 508, the working liquid 12 (or 14) from the cooling unit 25 or the condenser 40 are recirculated back to the plurality of heat exchangers 20. In some embodiments, before step 508, step 510 may be used.

At step 510, the liquid portion 12a and/or the second liquid portion 16 are combined in at least one vapor-liquid separator 50, and then fed back to the plurality of heat absorption devices 20.

In some embodiments, the system is in a closed loop and the working fluid is in gravity-driven circulation, or driven using a pump. The working fluid is a refrigerant fluid comprising one or more hydrofluorocarbon or other materials as described herein.

### EXAMPLES

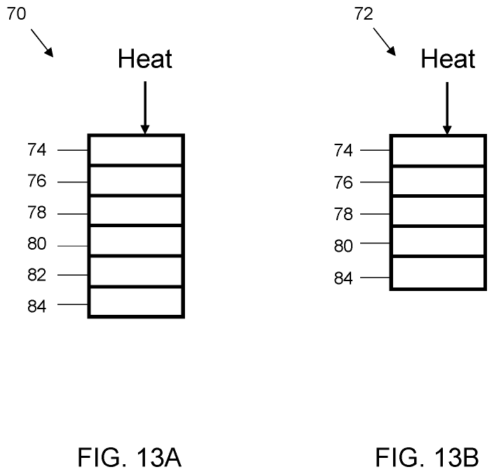

The operating temperatures of high-intensity electronic components such as processor chips can be calculated using a series-resistance thermal model as illustrated in FIGS. 13A and 13B. The model compares the temperature using cold plates (FIG. 13A) vs. air-cooled heat sinks (FIG. 13B). In the thermal model 70 or 72 as shown in FIGS. 13A-13B, a die 74, an electronic package 76, a thermal grease 78, a cold plate or heat sink 80, and a coolant 82 contact each other, and are in thermal communication with air 84. Using mid-range values of heat transfer coefficients of the cold plates or heat sinks based on values found in the heat transfer literature, an operating temperature for the systems described above can be calculated or estimated.

Assuming the indirect cooling portion of the heat load is subject to the same power-per-enclosure limitations as the enclosed indirect systems of FIGS. 6-8, the hybrid systems of FIG. 9-11 allow higher heat densities (total power-per-enclosure), because only a fraction of the total power is borne by the air coolers. The larger fraction of the total heat is absorbed by the cold plates. For example, when the electronic systems are data servers and the enclosure is a server cabinet, and the directly-cooled chips represent 75% of the total heat load, the hybrid system can handle a total of 12-32 kW heat load per cabinet, assuming the air coolers can handle 3-8 kW in the indirect systems.

The low-intensity air-cooled components are normally designed to operate in environments as high as 45° C., which is well above even summertime ambient temperatures in most locations. As illustrated below, the hybrid systems provided in the present disclosure allow all the components of the enclosed electronic systems, including high-intensity devices, to operate within their normal (internal) temperature limits.

The following examples are illustrative, and are based on the following assumptions or conditions:

(1) Electronics system comprising multiple data severs mounted on chassis, with components such as those depicted schematically in FIG. 1. The servers are mounted in racks or enclosures in a data center room.

(2) Each data server has four 80-watt processor chips, that can be directly cooled. either with air-cooled heat pipe heat sinks mounted onto the chips, or with liquid- or 2-phase cooled cold plates mounted in lieu of the heat sinks.

(3) 70% of a data server's heat generation is produced by the processor chips, and the remaining 30% of the heat is generated by the other components on the chassis, which are convectively cooled by air.

(4) Each server chassis has on-board fans to blow air across the air-cooled components. The fans provide enough air flow to limit the temperature rise of the air flowing though the chassis to 11.11° C. (20 degrees Fahrenheit). The chassis fans are assumed to be propeller-type axial fans delivering 2 inches water column differential air pressure, with a typical fan efficiency of 48%.

(5) Using the thermal resistance model of FIGS. 13A-13B, for processor chips cooled by air-cooled heat pipe heat sinks, the operating temperature of the processor chips at full power is 54° C. above the incoming chassis air temperature. When replaced by cold plates, the operating temperature of the processor chips at full power is 36° C. above the cold plate inlet coolant temperature.

(6) The air in a data center room is cooled to a “cold aisle” temperature of 20° C. (68 degrees Fahrenheit), using computer room air conditioning (CRAC) units with a 3.20 coefficient of performance, corresponding to a standard cooling system efficiency of 1.1 kW/ton of refrigeration.

(7) External ambient air temperature is 35° C. (95 degrees Fahrenheit), which is a common (summertime) design temperature, which limits the cooling capacity of the external (outdoor) heat exchanger.

(8) Data center room air is circulated between server racks and CRAC units using computer room air handler (CRAH) units, assuming blowers delivering 6 inches water column differential air pressure, with a typical blower efficiency of 72%.

(9) For fully enclosed cabinet-style server racks, indirect cooling via air-to-coolant air coolers is used. The cabinet air recirculation fans are assumed to be propeller-type axial fans delivering 2 inches water column differential air pressure, with a typical fan efficiency of 48%.

(10) Maximum air cooling capacity, which is limited by air flow across multiple servers, is 8 kW per rack or cabinet.

(11) A 2-phase coolant is used for cold plates, with an inlet coolant inlet temperature 5.4 degrees Fahrenheit (3° C.) above the external ambient air temperature, based on reasonable temperature approached for outdoor air-cooled heat exchangers.

(12) Power consumption of fans and blowers is calculated using the standard engineering fan equation: HP=dP/(6356× Eff), where HP=horsepower, dP=differential pressure in inches of water column, and Eff=fan or blower mechanical efficiency.

The calculations are made using the following examples. The results are summarized and compared in Table 1.

TABLE 1

| | Examples | | | |
|---|---|---|---|---|
| | Example 1 | Example 2 | Example 3 | Example 4 |
| Cooling conditions | Conventional | 2-Phase Coolant With | | |
| | | Passive Circulation | | |
| | Air Cooling | Direct | Indirect | Hybrid |
| Remote/external | 0% | 70% | 100% | 100% |
| heat rejection | | | | |
| Max air cooling | 8 | 8 | 8 | 8 |
| power per rack (kW) | | | | |
| Avg. # Servers per | 16 | 54 | 16 | 54 |
| rack | | | | |
| IT capacity increase | — | 238% | 0% | 238% |
| (%) | | | | |
| Avg. IT power per | 7.31 | 24.69 | 7.31 | 24.69 |
| rack (kW) | | | | |
| Total power per rack | 7.88 | 25.25 | 7.88 | 25.25 |
| (kW) | | | | |
| Heat removed by air | 7.88 | 7.97 | 7.88 | 7.97 |
| (kW/rack) | | | | |
| Server coolant inlet T | 22.2 | 38 | 38 | 38 |
| (° C.) | | | | |
| Coolant chilling (—) | −12.8 | 3 | 3 | 3 |
| or above-ambient | | | | |
| (° C.) | | | | |
| Server air outet T | 33.3 | 44.7 | 44.7 | 44.7 |
| (° C.) | | | | |
| Max CPU T (° C.) @ | 76.2 | 74 | 92 | 74 |
| full load | | | | |
| Power consumption | | | | |
| (Watts per server) | | | | |
| Processors | 320.0 | 320.0 | 320.0 | 320.0 |
| Other electronic | 137.1 | 137.1 | 137.1 | 137.1 |
| components | | | | |
| Theoretical Server | 457.1 | 457.1 | 457.1 | 457.1 |
| power | | | | |
| Server fans | 35.1 | 10.5 | 35.1 | 10.5 |
| CRAH | 70.1 | 21.0 | — | — |
| CRAC | 143.0 | 42.9 | — | — |
| Air Cooler Fans | — | — | 35.1 | 10.5 |
| Power consumed for | 248.2 | 74.5 | 70.1 | 21.0 |
| cooling | | | | |
| TOTAL SERVER | 705.3 | 531.6 | 527.3 | 478.2 |
| POWER | | | | |
| CONSUMPTION | | | | |
| Total power/ | 1.54 | 1.16 | 1.15 | 1.05 |
| theoretical electronics | | | | |
| power | | | | |
| % of Power for | 35.2% | 14.0% | 13.3% | 4.4% |
| Cooling | | | | |
| Cooling power | | 70.0% | 71.7% | 91.5% |
| reduction | | | | |
| Overall Energy | 0.0% | 24.6% | 25.2% | 32.2% |
| savings per server | | | | |
| (%) | | | | |

### Example 1: Conventional Air Cooling of Data Center Electronics

Example 1 follows the configuration of FIG. 2. Using the above assumptions, while the heat generated by the electronic components is 457 watts, the on-board chassis fans consume an additional 35 watts, the CRAH power consumption averages 70 watts per server, and the CRAC power consumption averages 143 watts per server. Thus the entire computer room requires an average of 705 watts per server, of which 35.2% is consumed by the cooling systems.

To stay within the 8 kW/rack air cooling capacity limit, the system can accommodate a maximum of 16 servers per rack (8.88 kW air cooling heat load per rack). The operating temperature of processor chips is 76.2° C. at full load.

### Example 2: Passive 2-Phase Cooling of Data Server Processors, with Room Air Cooling of Remainder of Server Electronics

Example 2 follows the configuration of FIG. 5, as it is the most energy-efficient configuration among the direct cooling options. Using the above assumptions, while the heat generated by the electronic components is 457 watts, the on-board chassis fans consume power consumption is 11 watts, the CRAH power consumption averages is 21 watts per server, and the CRAC power consumption is 43 watts per server. Thus the entire computer room requires an average of 532 watts per server, of which 14.1% is consumed by the cooling systems.

To stay within the 8 kW/rack air cooling capacity limit, the system can accommodate a maximum of 54 servers per rack (7.97 kW air cooling heat load per rack).

The operating temperature of processor chips is 74° C. at full load.

While the direct 2-phase cooling approach allows more than triple the computing density and represents a nearly 70% reduction in cooling power requirements and nearly 25% reduction in total power consumption compared to conventional air cooling, it nonetheless results in 30% of the heat being rejected into the computer room, which in turn still requires air conditioning (albeit at reduced load) to prevent overheating.

### Example 3: Enclosed Indirect Air Cooling of Data Servers Using Air-to-2-Phase Air Coolers Exhausting the Heat to an Ambient-Air-Cooled External Heat Exchanger

Example 3 follows the configuration of FIG. 8, as it is the most energy-efficient configuration among the enclosed indirect cooling options. Using the above assumptions, while the heat generated by the electronic components is 457 watts, the on-board chassis fans consume power consumption is 35 watts, the CRAHs and CRACs are turned off, and the fans for the air cooler consume an average of 35 watts per server. Thus an entire computer room hosting only such enclosed cabinets requires an average of 527 watts per server, of which 13.3% is consumed by the cooling systems.

To stay within the 8 kW/rack air cooling capacity limit, as with the conventional air cooling, the system can accommodate a maximum of 16 servers per rack (7.88 kW air cooling heat load per rack).

The operating temperature of processor chips is 92° C. at full load. This is substantially higher than with conventional air cooling, and close to the typical 100° C. operating limit for processors, because the enclosed air temperature is un-chilled.

While the enclosed indirect cooling approach offers the advantage of reducing the computer room infrastructure requirements (CRAHs and CRACs not needed), and offers the low energy consumption comparable to the direct-cooling approach, it does not facilitate an increase in server density, and may have the disadvantage if higher processor operating temperatures, which can reduce the life and efficiency of the chips.

### Example 4: Enclosed Hybrid (Direct and Indirect) Cooling of Data Servers Using Passive 2-Phase Cold Plates and Air Coolers Exhausting the Heat to an Ambient-Air-Cooled External Heat Exchanger

Example 4 follows the configuration of FIG. 11, which may be the most energy-efficient configuration among the enclosed hybrid cooling options. Using the above assumptions, while the heat generated by the electronic components is 457 watts, the on-board chassis fans consume power consumption is 11 watts, the CRAHs and CRACs are turned off, and the fans for the air cooler consume an average of 11 watts per server. Thus an entire computer room hosing only such enclosed hybrid cabinets requires an average of 479 watts per server, of which 4.6% is consumed by the cooling systems.

To stay within the 8 kW/rack air cooling capacity limit, as with the open-rack direct cooling, the system can accommodate a maximum of 54 servers per cabinet (7.97 kW air cooling heat load per rack).

As with the direct cooling configuration, the operating temperature of processor chips is 74° C. at full load.

Example 4 illustrates the advantages of the hybrid system provided in the present disclosure. The system offers the ability to maximize the IT density while remotely rejecting the entirety of the heat generated by the enclosed electronics, minimizing the total energy consumption, and reducing the computer room infrastructure requirements (CRAHs and CRACs not needed). The processor operating temperatures remain within the normal range of air-cooled systems, without the need to chill the air. Cooling power requirements are minimized. For example, Example 4 needs 91% less of cooling power, compared to conventional air cooling in Example 1, and 71% less than that in open-rack direct cooling. Server power requirements are reduced to close to theoretical minimum.

The systems described in the present disclosure may also include other components such as a compressor, and an expansion device, which are described in a co-pending application, U.S. application Ser. No. 16/593,117 filed Oct. 4, 2019, claiming the benefit of U.S. Provisional Application No. 62/741,819. The co-pending application is expressly incorporated by reference herein in its entirety.

Although the subject matter has been described in terms of exemplary embodiments, it is not limited thereto. Rather, the appended claims should be construed broadly, to include other variants and embodiments, which may be made by those skilled in the art.

What is claimed is:

1. A system for cooling heat-generating electronic devices, comprising:
a plurality of heat exchangers in thermal communication with a plurality electronic devices, each of the plurality of heat exchangers comprising at least one channel configured to receive and circulate a working liquid,
wherein the plurality of heat exchangers include at least one cold plate configured to contact at least one of the plurality of electronic device,
and at least one air cooler configured to circulate air to and convectively absorb heat from one or more electronic devices.

2. The system of claim 1, wherein the plurality of heat exchangers and a plurality electronic devices are disposed in an enclosure.

3. The system of claim 1, wherein the plurality of heat exchangers are in a closed-loop circulation of the working fluid, and the at least one cold plate and at least one air cooler are connected in parallel.

4. The system of claim 1, wherein the system is in a closed loop and the working fluid is in gravity-driven circulation.

5. The system of claim 1, further comprising a pump configured to circulate the working liquid to the plurality of heat exchangers.

6. The system of claim 1, wherein the working liquid is configured to remain in liquid form, each of the plurality of heat exchangers is configured to be liquid-cooled heat absorbers, wherein the working liquid exits from the plurality of heat exchangers with a temperature increase.

7. The system of claim 6, further comprising a cooling unit configured to cool the working liquid from the plurality of heat exchangers so as to release heat.

8. The system of claim 6, further comprising an expansion tank configured to provide additional volume to accommodate thermal expansion of the working liquid.

9. The system of claim 1, wherein the working liquid is evaporable and configured to become a first 2-phase mixture having a first liquid portion and a first vapor portion upon absorption of heat.

10. The system of claim 9, further comprising at least one condenser configured to condense the first vapor portion to a second liquid portion so as to release heat.

11. The system of claim 10, further comprising at least one vapor-liquid separator configured to feed the first liquid portion and/or the second liquid portion back to the plurality of heat exchangers.

12. The system of claim 1, wherein the working liquid is a refrigerant fluid comprising one or more hydrofluorocarbon materials.

13. A system for cooling heat-generating electronic devices, comprising:
a plurality of heat exchangers in thermal communication with a plurality electronic devices disposed in an enclosure, each of the plurality of heat exchangers comprising at least one channel configured to receive and circulate an evaporable working liquid, the working liquid configured to become a first 2-phase mixture having a first liquid portion and a first vapor portion upon absorption of heat,
wherein the plurality of heat exchangers include at least one cold plate configured to contact at least one of the plurality of electronic device, and at least one air cooler configured to circulate air to and convectively absorb heat from one or more electronic devices, and
wherein the plurality of heat exchangers are in a closed-loop circulation of the working fluid, and the at least one cold plate and at least one air cooler are connected in parallel.

14. The system of claim 13, wherein the at least one cold plate includes a plurality of code plates connected in parallel.

15. The system of claim 13, further comprising at least one condenser configured to condense the first vapor portion to a second liquid portion so as to release heat.

16. The system of claim 13, further comprising at least one vapor-liquid separator configured to feed the first liquid portion back to the plurality of heat exchangers.

17. A method for cooling heat-generating electronic devices using the system of claim 1, comprising:
providing the working liquid to the plurality of heat exchangers to absorb heat generated by the plurality electronic devices;
supplying the working liquid exiting from the plurality of heat exchangers to a cooling unit or a condenser so as to release the heat; and
recirculating the working liquid from the cooling unit or the condenser back to the plurality of heat exchangers.

18. The method of claim 17, wherein the working liquid exiting from at least one of the plurality of heat exchanger remains in liquid form, and is cooled by the cooling unit.

19. The method of claim 17, wherein the working liquid exiting from at least one of the plurality of heat exchanger becomes a first 2-phase mixture having a first liquid portion and a first vapor portion upon absorption of heat.

20. The method of claim 19, further comprising:
condensing the first vapor portion to a second liquid portion using the condenser; and
feeding the first liquid portion and/or the second liquid portion back to the plurality of heat absorption devices from at least one vapor-liquid separator.

21. The method of claim 20, wherein the system is in a closed loop and the working fluid is in gravity-driven circulation.

22. The method of claim 20, wherein the working fluid is a dielectric refrigerant fluid.
